(19) United States
(12) Patent Application Publication
(10) Pub. No.: US 2024/0322298 A1
(43) Pub. Date: Sep. 26, 2024

(54) METHODS AND SYSTEMS FOR A THERMAL MANAGEMENT SYSTEM

(71) Applicant: Ford Global Technologies, LLC, Dearborn, MI (US)

(72) Inventor: Hans Guenter Quix, Herzogenrath (DE)

(21) Appl. No.: 18/613,710

(22) Filed: Mar. 22, 2024

(30) Foreign Application Priority Data
Mar. 23, 2023 (DE) 102023107304.4

(51) Int. Cl. H01M 10/6569; B60H 1/00; B60L 58/27; H01M 10/613; H01M 10/625; H01M 10/633; H01M 10/663

(52) U.S. Cl. CPC H01M 10/6569; B60H 1/00278; B60L 58/27; H01M 10/613; H01M 10/625; H01M 10/633; H01M 10/663; B60H 2001/00307; H01M 2220/20

(57) ABSTRACT

Methods and systems are provided for a cooling system. In one example, the cooling system includes a battery section including a battery, an electronics section including a set of power electronics, a radiator section including a radiator, a storage section including a heat store, and a plurality of valves configured to control a fluid connection between each of the battery section, the electronics section, the radiator section, and the storage section.

### CROSS REFERENCE TO RELATED APPLICATION

The present application claims priority to German Patent Application No. 102023107304.4 filed on Mar. 23, 2023. The entire contents of the above-listed application is hereby incorporated by reference for all purposes.

### FIELD

The present description relates generally to a thermal management system for an electric vehicle.

### BACKGROUND/SUMMARY

Battery-electric vehicles (BEVs) include a battery, which constitutes the energy source of the vehicle, along with various electrical components which are used for the operation of the battery or of the drive motor. The electrical components may be referred to as “power electronics” and may include a charger, a DC-DC converter, and/or an inverter, for example. Both the battery and the set of power electronics may be cooled during driving operation and during a charging operation. Owing to the different cooling requirements, current vehicle systems may include two separate cooling systems for the power electronics and for the battery. For reasons relating to complexity and structural space, the battery system is typically cooled by the refrigerant circuit via a chiller. Also, in the presence of high ambient temperatures, cooling via the refrigerant circuit is requested in order to achieve the low temperature that is used for the cooling of the battery. Such a refrigerant circuit may include a condenser, an evaporator, and an electrically operated compressor. On the other hand, the set of power electronics is cooled via a separate cooling circuit, which may be connected to a frontally installed radiator.

A disadvantage of such systems is that, for the cooling of the battery system, it is desired for the electrical compressor in the refrigerant circuit to be activated, even though it would be possible in the presence of moderate and low ambient temperatures for the battery system to be cooled via a direct cooling system, such that the electrical energy for driving the compressor may be saved. Whilst driving operation or a charging operation demand cooling of the battery, it is desired in the presence of low ambient temperatures for the drive battery to be warmed up, for example via the cooling system using a positive temperature coefficient (PTC) heater, when the vehicle is started. The heating energy used for this is in turn taken from the battery itself, resulting in a reduced vehicle range.

DE 10 2018 101 518 A1 discloses a thermal system for a motor vehicle, having a refrigerant circuit for conditioning at least one air mass flow that is to be fed to a passenger compartment and for conditioning a component of a drivetrain, the refrigerant circuit having a compressor, a refrigerant-coolant heat exchanger, a first heat exchanger, which is operated as an evaporator and which has an expansion element arranged upstream, a second heat exchanger, which is operated as an evaporator and which has an expansion element arranged upstream, and a coolant circuit for absorbing heat from the refrigerant circuit. The coolant circuit has the refrigerant-coolant heat exchanger of the refrigerant circuit, a coolant-air heat exchanger for transferring heat to ambient air, and a heat store device.

DE 10 2019 100 096 B4 discloses an air-conditioning and battery cooling arrangement, having an A/C coolant circuit, an electric drivetrain coolant circuit and a refrigerant circuit, which are coupled to one another via a 4/2 directional coolant valve such that they may be operated separately or flow may pass through them in series. The A/C coolant circuit has an A/C coolant radiator for releasing heat to the ambient air, has a coolant pump, and has a condenser via which the A/C coolant circuit is thermally connected to the refrigerant circuit, and the electric drivetrain coolant circuit has a battery cooler, has a coolant pump, has a drivetrain coolant radiator, and has a chiller via which the electric drivetrain coolant circuit is thermally connected to the refrigerant circuit. The content of DE 10 2020 100 428 A1 is similar, wherein, furthermore, the 4/2 directional coolant valve is arranged so as to connect the outlet of the A/C coolant radiator to the inlet of the drivetrain coolant radiator, and a 3/2 directional valve at the outlet of the drivetrain coolant radiator is arranged to have a connection to the A/C coolant circuit.

DE 11 2012 001 744 B4 discloses a vehicle temperature control device, having a thermally capacitive element, a refrigeration circuit, a heat exchanger that causes the heat stored in the thermally capacitive element to be exchanged with a refrigerant of the refrigeration circuit, and a heat dissipation part that is designed to discharge the heat contained in the refrigerant of the refrigerant circuit to a temperature-control object. An interrupter interrupts the storage of heat in the thermally capacitive element and resumes the dissipation of heat from the heat dissipation part the temperature-control object, and a control device controls the interrupter on the basis of the result of a determination of the heat storage requirement, that is to say of whether the thermally capacitive element is required to store heat therein, wherein the control device controls the interrupter such that heat is firstly stored in the thermally capacitive element and is then discharged from the thermally capacitive element to the temperature-control object if the control device determines that the thermally capacitive element is required to store heat.

DE 11 2017 003 470 T5 discloses a temperature management system for a vehicle, comprising a refrigerant cycle for performing air-conditioning of the interior compartment of the vehicle. A compressor, a condenser, a first expansion valve and an evaporator, which is arranged in an air-conditioning system housing in order to exchange heat between the refrigerant and the air that is discharged into the interior compartment of the vehicle, are arranged in a refrigerant line. Said refrigerant line is a flow passage for the refrigerant, wherein a cooling system for electronic components, said cooling system being required for the autonomous driving of the vehicle, is connected to a refrigerant branch line that branches off from the refrigerant line.

In view of the cited previous examples, there may be demands for systems and methods that vary from those already available.

In one example, the issues described above are at least partially solved by a cooling system of a vehicle including a battery section comprising a battery, an electronics section comprising a set of power electronics, a radiator section comprising a radiator, a storage section comprising a heat store, and a plurality of valves configured to control a fluid connection between each of the battery section, the electronics section, the radiator section, and the storage section.

It should be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE DRAWINGS

The advantages described herein will be more fully understood by reading an example of an embodiment, referred to herein as the Detailed Description, when taken alone or with reference to the drawings, where:

FIG. 1 is a schematic illustration of a cooling system according to the disclosure, with a valve arrangement in a first state;

FIG. 2 is an illustration of the cooling system from FIG. 1, with the valve arrangement in a variant of the first state;

FIG. 3 is an illustration of the cooling system from FIG. 1, with the valve arrangement in a second state;

FIG. 4 is an illustration of the cooling system from FIG. 1, with the valve arrangement in a third state;

FIG. 5 is an illustration of the cooling system from FIG. 1, with the valve arrangement in a fourth state; and

FIG. 6 is a flow diagram showing processes within the cooling system of FIG. 1.

### DETAILED DESCRIPTION

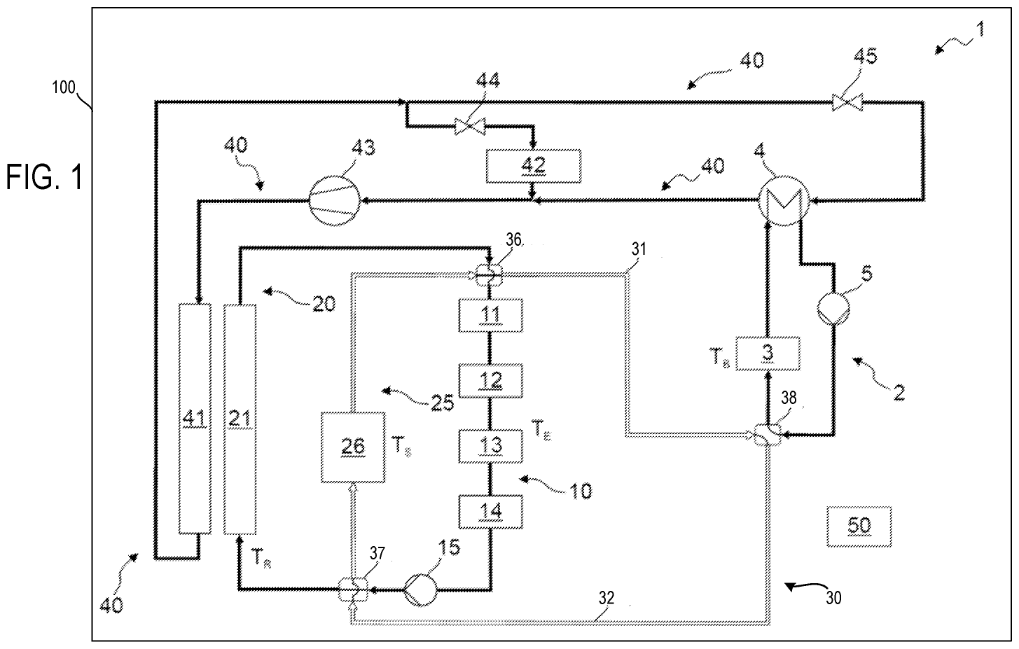

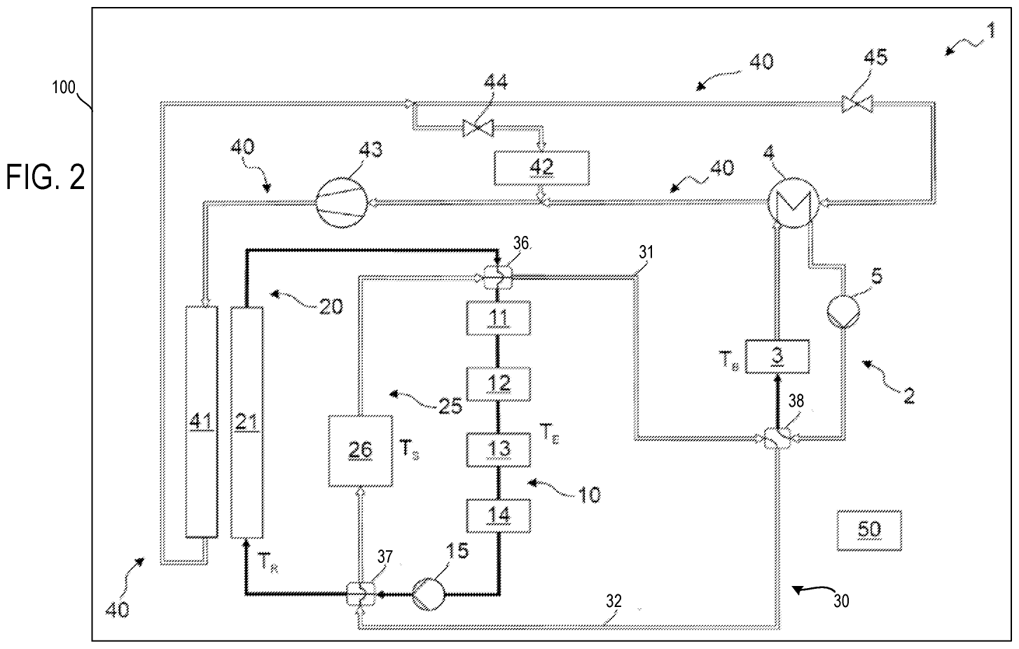

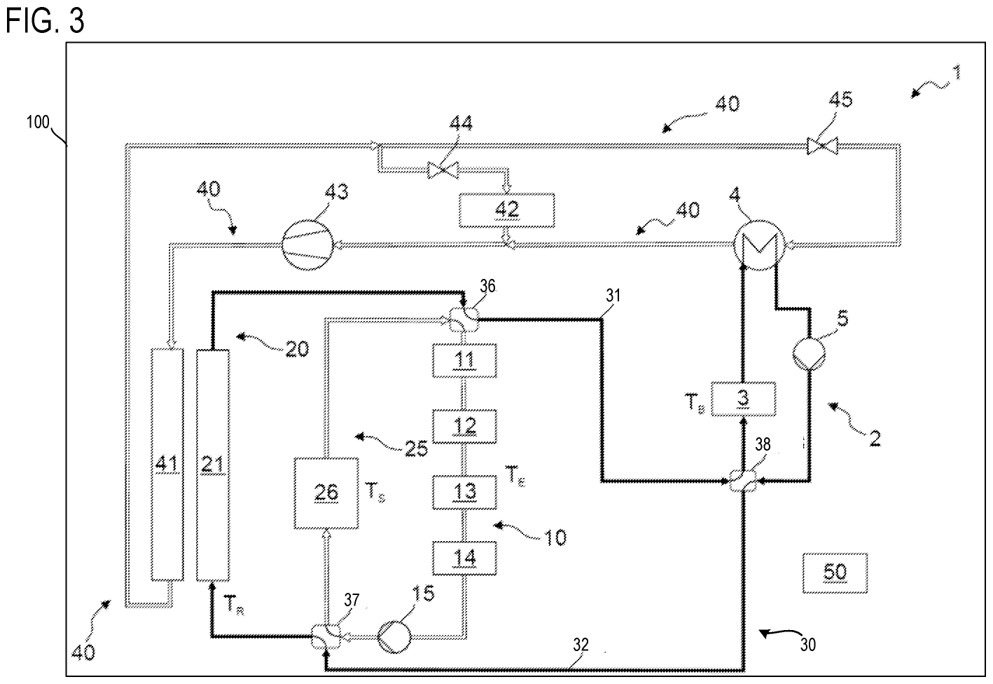

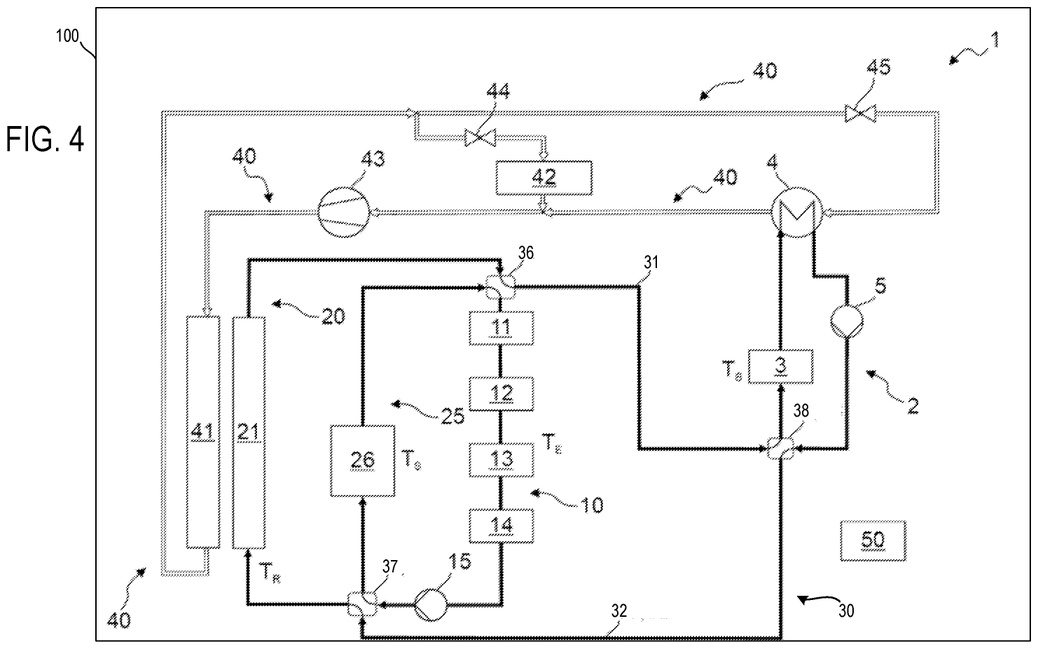

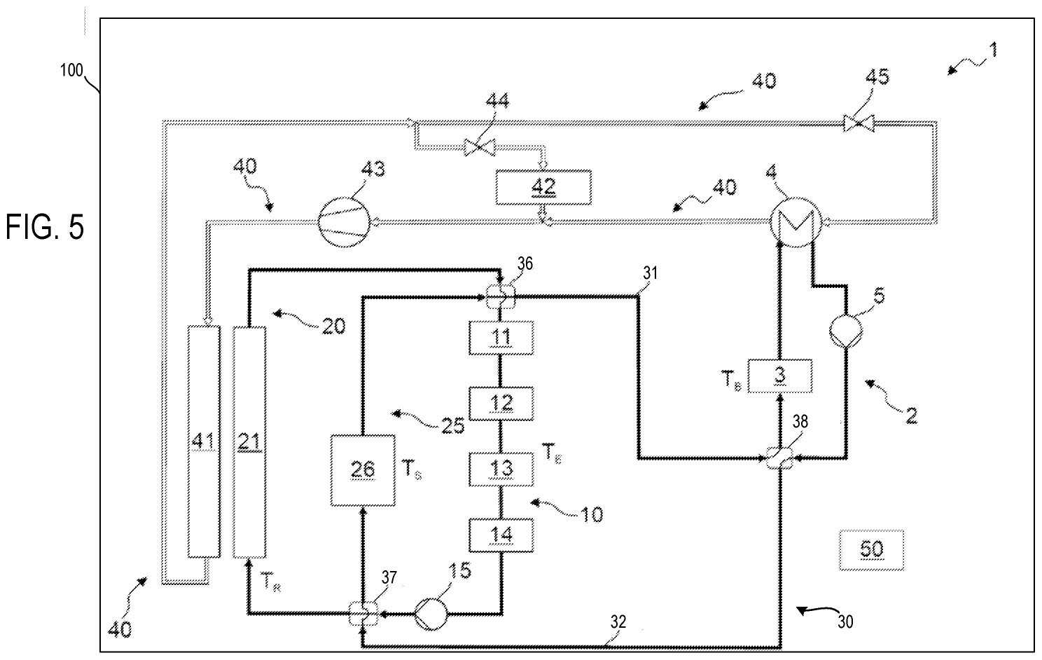

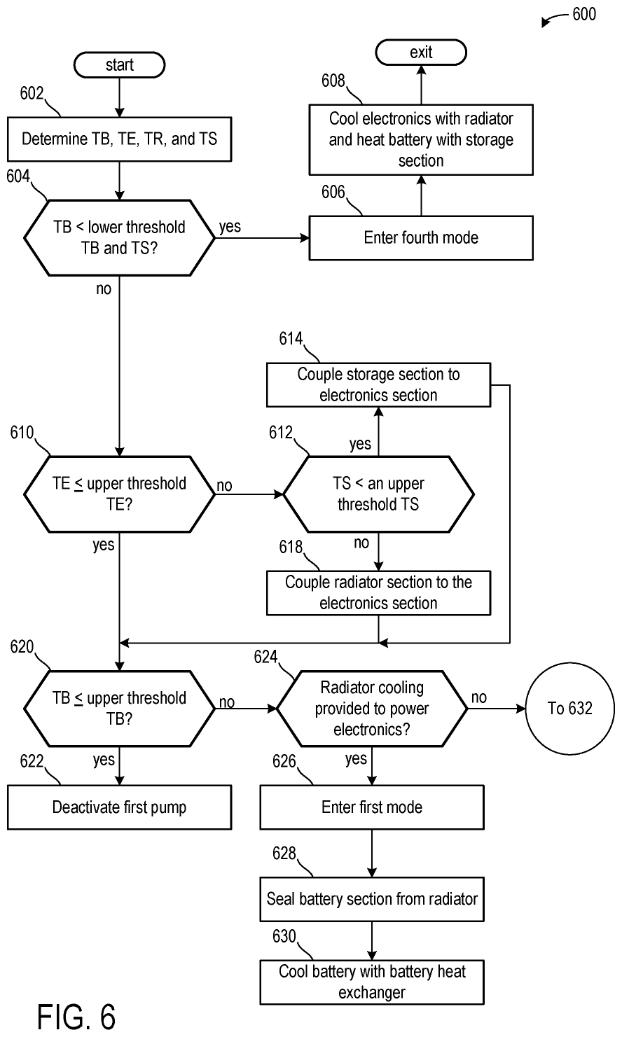

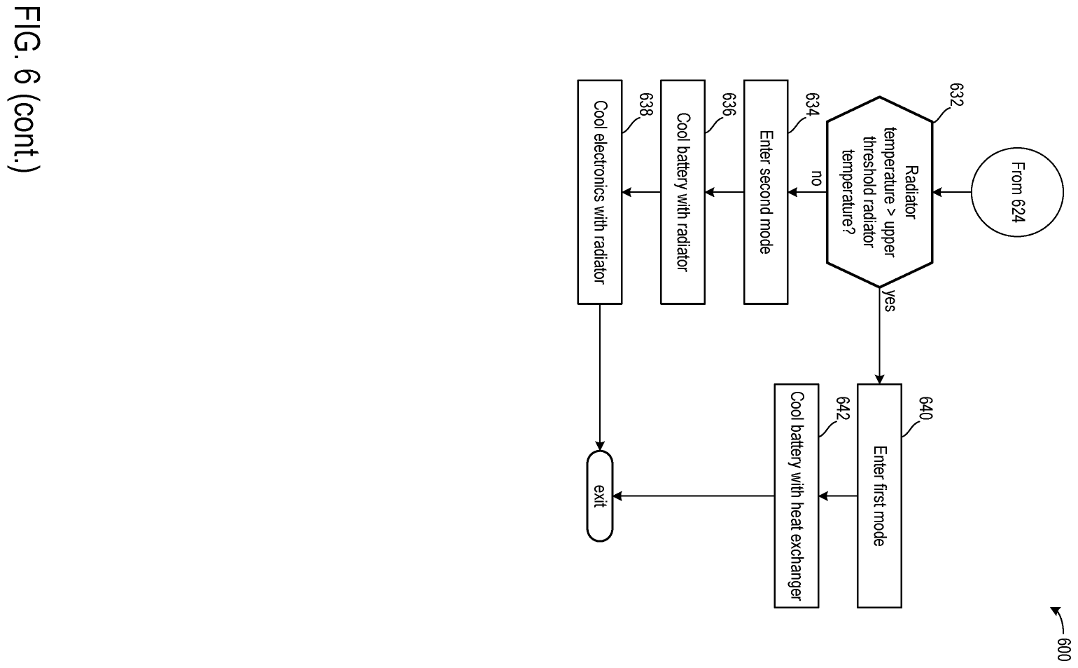

The following description relates to systems and methods for a cooling system for a vehicle. FIG. 1 is a schematic illustration of a cooling system according to the disclosure, with a valve arrangement in a first state. FIG. 2 is an illustration of the cooling system from FIG. 1, with the valve arrangement in a variant of the first state. FIG. 3 is an illustration of the cooling system from FIG. 1, with the valve arrangement in a second state. FIG. 4 is an illustration of the cooling system from FIG. 1, with the valve arrangement in a third state. FIG. 5 is an illustration of the cooling system from FIG. 1, with the valve arrangement in a fourth state. FIG. 6 is a flow diagram showing processes within the cooling system of FIG. 1.

It should be noted that the features and measures specified individually in the following description may be combined with one another in any desired technically meaningful way and disclose further embodiments of the disclosure. The description additionally characterizes and specifies the disclosure, in particular in conjunction with the figures.

The disclosure provides a cooling system for an electric vehicle. The cooling system is provided for motor vehicles such as heavy goods vehicles or passenger cars, but may be provided in rail vehicles or watercrafts. Here, the term “electric vehicle” generally denotes a vehicle that has at least one electric motor that serves for driving the vehicle. In particular, the vehicle may be a purely electrically operated vehicle, but this does not rule out use of the disclosure in hybrid vehicles. The term “cooling system” generally means that at least some components of the cooling system are at least intermittently used for thermally managing components of the electric vehicle. The cooling system may provide cooling or heating effects based on operating conditions. It is also possible for components that are not used for cooling to be regarded as part of the cooling system. This relates inter alia to components which are cooled, and to components which control the actual cooling components or assist these in terms of their function. Here and below, “cooling” of a component refers to the dissipation of heat from the component. The temperature of the component may thus be reduced, though it may also be the case that said temperature is merely kept constant, or a temperature increase is slowed.

The cooling system has a battery section for cooling a battery, has an electronics section for cooling a set of power electronics, and has a radiator section comprising a radiator. The terms “battery section”, “electronics section” and other sections yet to be mentioned below refer to parts of a system which, during operation, receives and conducts a liquid coolant. The coolant is normally water or an aqueous solution or an aqueous mixture, for example a water-glycol mixture. Each “section” may also be referred to as a “branch” or the like, that is to say, for example, “battery branch”. A section may be linear or may be the form of a closed loop. Likewise, it may be branched or non-branched. The battery section is configured for cooling a battery, wherein the term “battery” expressly also includes battery packs which, strictly speaking, are assembled from multiple individual batteries. The battery section may also be provided for cooling multiple physically spaced-apart batteries. Here, the battery section is in direct thermal contact with the associated battery to exchange heat therewith. Correspondingly, the electronics section is provided for thermally managing a set of power electronics, which may be assigned to the battery or to a drive motor and/or may assist either. Said set of power electronics may for example involve a charger, a DC-DC converter, an inverter, or the like. The electronics section may however also be provided for cooling a drive motor or a transmission (via a transmission oil cooler). Said electronics section is normally in direct thermal contact with the components that are to be cooled. Optionally, both the battery and the components that are to be cooled by the electronics section may be regarded as parts of the cooling system. The radiator section likewise serves for conducting liquid coolant. Said radiator section has a radiator, which in this context refers to an air/liquid heat exchanger. During operation, the corresponding radiator receives cooling liquid, or is passed through by a flow of said cooling liquid, whilst being in contact at the other side with the ambient air. The radiator is typically installed at the front of the vehicle, where it may be optimally impinged on by air flow.

According to the disclosure, the cooling system has a storage section including a heat store, and has a connecting arrangement and a valve arrangement which, depending on its setting, connects the radiator section either to the electronics section or via the connecting arrangement to the battery section, bypassing the storage section, and which, depending on its setting, connects the electronics section either to the radiator section, bypassing the storage section, or to the storage section, bypassing the radiator section.

The storage section is configured to conduct coolant. Said storage section has a heat store that is configured to absorb heat, to store said heat and to release it again. In particular, the heat store is in direct or indirect contact with the coolant so as to be able to exchange heat therewith. The storage mechanism may in the simplest case be based on the storage of sensible heat, wherein any absorption of heat leads to an increase in temperature of the heat store. In this case, the heat store may advantageously have the largest possible heat capacity. This may be achieved by way of a high mass and/or a material that has a high specific heat capacity, with the former being expedient only to a limited extent because it is generally sought to minimize the total mass of the vehicle. A latent heat store that absorbs the heat energy, and releases it again, in the course of a phase transformation may also be used. A further option is a thermochemical heat store that absorbs the heat energy by way of an endothermic reaction and releases said heat energy by way of an exothermic reaction. Combinations of different storage mechanisms are also possible.

The connecting arrangement is likewise configured to conduct coolant. Said connecting arrangement is interposed between the battery section, on the one hand, and the storage section and the radiator section, on the other hand. Said connecting arrangement normally has two parts, which may be referred to as a first connecting section and a second connecting section. One of the connecting sections serves to discharge coolant from the battery section, and the other serves to return said coolant to the battery section.

The valve arrangement normally has multiple valves, which may at least in part be spatially separate. The valve arrangement may include directional valves and/or shut-off valves. Via the valve arrangement, different connections within the cooling system may be established, wherein a “connection” refers to a fluid-conducting or a fluidic connection. Firstly, depending on a setting, that is to say depending on the setting of the valve arrangement, the radiator section may be connected either to the electronics section or via the connecting arrangement to the battery section. In each of these cases, the storage section is bypassed, that is to say the corresponding connection bypasses the storage section, such that the radiator section is fluidly separated from the storage section. As a result, either the electronics section or the battery section may be connected to the radiator section. This allows the radiator to be used alternatively either for cooling the set of power electronics or for cooling the battery.

Furthermore, depending on a setting, the electronics section may be connected either to the radiator section, bypassing the storage section, or to the storage section, bypassing the radiator section. That is to say, depending on the setting of the valve arrangement, there are two alternative connection options for the electronics section, specifically either exclusively to the radiator section, that is to say bypassing the storage section, or else exclusively to the storage section, that is to say bypassing the radiator section. The at least one set of power electronics may thus either be cooled via the radiator or may, indirectly, via the coolant, release heat to the heat store, which likewise results in cooling of the set of power electronics.

The cooling system according to the present disclosure allows various components, in particular the battery, to be cooled efficiently. The battery may optionally be cooled via the radiator, which involves little consumption of energy. Whilst the battery is being cooled via the radiator, it may not be possible for the set of power electronics to be cooled via the radiator. If there is a demand for cooling, heat from the electronics section may be deposited in the heat store whilst the battery continues to be cooled via the radiator. This is appropriate in particular when brief power peaks occur in the set of power electronics. No additional heat exchanger is desired to cool the set of power electronics during this time. Furthermore, the thermal energy that is stored in the heat store may be released again via the coolant and possibly utilized to warm up components that are at too low a temperature.

In general, the battery section has a battery heat exchanger which is in thermal contact with a refrigerant circuit, wherein a coolant flow may be generated through the battery section including the battery heat exchanger. The refrigerant circuit serves for conducting a refrigerant and generally has a compressor, a condenser and an evaporator. The refrigerant is conveyed via the (normally electrically driven) compressor and is liquefied under pressure in the condenser, where it releases heat. A transformation into the gaseous state occurs in the evaporator, with heat being absorbed. The refrigerant circuit may in particular be assigned to an air-conditioning system of the vehicle, wherein, in this embodiment, said refrigerant circuit may also be used for cooling the battery. The battery heat exchanger may also be referred to as a chiller. It is a liquid-liquid heat exchanger in which the coolant of the battery section exchanges heat with the refrigerant of the refrigerant circuit, generally releases heat to the refrigerant. This cooling is highly effective and is possible even in the presence of high ambient temperatures. However, the operation of the compressor involves considerable consumption of energy, which is normally drawn from the battery. The cooling system is therefore configured to at least temporarily reduce a refrigerant flow through the battery heat exchanger when the battery section is connected via the connecting arrangement to the radiator section. In this case, the battery may be cooled entirely or predominantly via the radiator, such that the cooling via the battery heat exchanger may be reduced. Here, the term “reduce” expressly includes the possibility of the refrigerant flow being stopped or interrupted. Here, either the power of the compressor may be reduced (possibly to zero), or a part of the refrigerant circuit in which the battery heat exchanger is arranged may be entirely or partially bypassed.

One embodiment provides for the cooling system to be operable in a first mode in which the valve arrangement is set such that the battery section is separated from the radiator section and from the storage section and the electronics section is connected to the radiator section, bypassing the storage section, wherein a coolant flow is generated through the electronics section and the radiator section. Where it is stated here and below that a “coolant flow is generated”, it is generally the case that at least one pump unit generates the coolant flow, that is to say actively conveys coolant. The pump unit is normally an electric pump. In the first mode, the cooling of the set of electronics is executed via the radiator, and accordingly, the electronics section and the radiator section are connected and passed through by a flow of coolant. Here, the coolant flow circulates through the electronics section and the radiator section, wherein the coolant flow may also pass through other parts of the cooling system. By contrast, the battery section is separated from the radiator section, such that the radiator is not laden with waste heat from the battery. The battery section is also separated from the storage section, because the heat store is not capable of absorbing heat from the battery for relatively long periods of time. If cooling of the battery is desired in the first mode, this is executed via the battery heat exchanger.

The cooling system is furthermore advantageously operable in a second mode in which the valve arrangement is set such that the battery section is connected via the connecting arrangement to the radiator section, bypassing the storage section, and the electronics section is separated from the radiator section, wherein a coolant flow through the electronics section is stopped whilst a coolant flow is generated through the battery section and the radiator section. In this mode, the battery section is thus connected to the radiator section but not to the storage section. Via the coolant flow that is generated, heat is transferred from the battery to the radiator, where it may be released to the ambient air. As already discussed above, a refrigerant flow through the battery heat exchanger is at least temporarily reduced such that the refrigerant circuit may be relieved of load. The second mode may be used when the battery is cooled whilst the at least one set of power electronics does not request to be cooled. Accordingly, the coolant flow through the electronics section is stopped. In other words, because the electronics section does not request to be cooled by the radiator, the radiator may be used for cooling the battery. The terms “first mode”, “second mode” etc. are generally used merely for terminological distinction, and do not imply a chronological or other sequence. Also, the implementation of, for example, the second mode in an embodiment does not mean that the first mode also has to be implemented.

The cooling system may furthermore be operable in a third mode in which the valve arrangement is set such that the battery section is connected via the connecting arrangement to the radiator section, bypassing the storage section, and the electronics section is connected to the storage section, bypassing the radiator section, wherein a coolant flow is generated through the battery section and the radiator section and a coolant flow is generated through the electronics section and the storage section. This mode is similar to the second mode. Temperature control, in particular cooling, of the electronics section is however additionally performed here. Here, the cooling of the battery via the radiator is maintained, and heat is transferred between the electronics section and the heat store. Normally, heat is transferred from the electronics section to the heat store. Even though the heat store is not provided for discharging heat from the cooling system, it may be used for a certain period of time to cool the electronics section. Thus, during this time, the radiator may be used exclusively for cooling the battery. The third mode is suitable in particular for covering temporary load peaks in the electronics section. If the heat store is used for longer periods of time, its storage capacity will ultimately be exhausted. In this case, the electronics section may again be cooled by the radiator, and the battery may be cooled via the battery heat exchanger and the refrigerant circuit, which corresponds to the first mode.

The cooling system may furthermore be operable in a fourth mode in which the valve arrangement is set such that the battery section is connected via the connecting arrangement to the storage section, bypassing the radiator section, and the electronics section is connected to the radiator section, bypassing the storage section, wherein a coolant flow is generated through the battery section and the storage section and a coolant flow is generated through the electronics section and the radiator section. This fourth mode, in which there is a connection between the heat store and the battery, may be used in two ways. Firstly, the heat store, if it has correspondingly stored heat, may be used to enhance the warm-up of the battery in the event of a cold start. Since, in the event of a cold start, the heat store is initially at a low temperature similar to that of the battery, this variant may be used only if the heat store is configured for example as a latent heat store or thermochemical heat store, such that the previously stored latent heat or chemical energy may be released again. In this variant, no cooling is executed via the refrigerant circuit. Another possibility includes cooling the heat store via the battery section and the refrigerant circuit, in order that said heat store may later be used again as a short-term store. Such cooling of the heat store briefly increases energy consumption, but may nevertheless be expedient under certain circumstances because, for example, it is made possible for the above-described second mode to be used at a later point in time.

Yet further possible uses are conceivable in addition to the four modes described here. For example, a connection may be established between the storage section and the radiator section to cool the heat store via the radiator. Also, in a variant of the fourth mode, the coolant flow through the electronics section and the radiator section may be stopped, because under some circumstances the set of electronics initially does not demand cooling in the event of a cold start.

One embodiment provides for the cooling system to be configured to at least indirectly determine a store temperature of the heat store and an electronics temperature of the set of power electronics and, if the electronics temperature exceeds a first threshold temperature, to cool the set of power electronics via the radiator if the store temperature is higher than a second threshold temperature and to otherwise cool the set of power electronics via the heat store. The aforementioned temperatures are determined at least indirectly. This includes the possibility of the temperature of the object being measured directly. It would however also be possible to measure a temperature of another object, from which the temperature may be inferred, for example because said temperatures are identical or have a known relationship to one another. It would finally also be possible to measure some other physical variable from which the temperature may be inferred. Depending on the embodiment, the temperature may be determined approximately. Firstly, a store temperature of the heat store is determined. It would also be conceivable to determine the temperatures at different points and to form an average value from these. Correspondingly, the electronics temperature may be a temperature of one component of the set of power electronics, or may be an average value calculated from temperatures of different components. It would also be conceivable to select the highest temperature value from among several components. The electronics temperature may also be determined indirectly, for example by measuring a temperature in the coolant of the electronics section. The electronics temperature is compared with a first threshold temperature. This threshold temperature, which may also be referred to as a limit temperature, represents a limit below which the set of power electronics operates optimally and is protected against thermal degradation. If this temperature is overshot, countermeasures may be implemented. The store temperature is taken into consideration in selecting the countermeasure. If said store temperature is higher than a second threshold temperature, then the heat store is too warm and is therefore unsuitable for cooling. Even though a terminological distinction is made between the first threshold temperature and the second threshold temperature, these may be of identical value. It could thus be argued that the heat store may be used to absorb heat if it is at the first threshold temperature that represents the temperature limit of the set of power electronics. The second limit temperature may be lower than the first limit temperature. If the second limit temperature is exceeded, the set of power electronics may be cooled via the radiator, wherein the cooling system connects the electronics section to the radiator section and generates a corresponding coolant flow. Otherwise, cooling may be performed via the heat store, such that the cooling system connects the electronics section to the storage section and generates a corresponding coolant flow.

A further embodiment provides for the cooling system to be configured to at least indirectly determine a battery temperature of the battery and a radiator section temperature of the radiator section and, if the battery temperature exceeds a third threshold temperature, to cool the battery via the battery heat exchanger if the radiator section temperature is higher than a fourth threshold temperature or the electronics section is connected to the radiator section, and to otherwise cool the battery via the radiator. The radiator section temperature may be a temperature of a cooling liquid line within the radiator section, or a temperature of the radiator itself. It is however preferable for a temperature of the cooling liquid in the radiator section to be determined. In this embodiment, it is firstly checked whether the battery temperature is higher than the third threshold temperature. Said third threshold temperature normally represents a temperature up to which the battery may operate optimally. If the third threshold temperature is overshot, the battery may be cooled. If possible and expedient, the radiator may be used for this purpose, such that the cooling system connects the battery section to the radiator section via the connecting arrangement and generates a corresponding coolant flow. However, if the radiator section temperature exceeds a fourth threshold temperature, this is evaluated as a sign that effective cooling is no longer provided by the radiator. Here, the fourth threshold temperature may in turn be identical to, but is normally lower than, the third threshold temperature. A further situation in which the system does not use radiator-based cooling is one in which the electronics section is connected to the radiator section, that is to say the set of power electronics is presently being cooled via the radiator. To ensure effective cooling of the electronics section in this case, the electronics section remains connected to the radiator section. In this case, the battery may be cooled via the battery heat exchanger, and therefore the cooling system separates the battery section from the radiator section and from the storage section and generates a coolant flow through the battery and the battery heat exchanger. The refrigerant circuit is also activated or kept active.

There is a wide variety of possibilities with regard to the configuration of the valve arrangement. One embodiment provides for the valve arrangement to have a first valve unit and a second valve unit which are configured to, depending on their setting, either connect the radiator section to the connecting arrangement and connect the storage section to the electronics section, or connect the radiator section to the electronics section and connect the storage section to the connecting arrangement. Here and below, the term “valve unit” means that said unit has at least one valve, and possibly multiple valves. The term may not be interpreted as meaning that the valve unit as a whole is physically contiguous. It could for example have multiple valves which are spatially separated but which may be actuated in a coordinated manner. If the first or second valve unit is formed by a single valve, this is arranged at a point at which the radiator section, the storage section, the electronics section and the connecting arrangement meet. In a first setting, the first or second valve unit connects the radiator section to the connecting arrangement (which allows the radiator section to be connected to the battery section) and connects the storage section to the electronics section. This setting may be selected for example in the third mode. In a second setting, the first or second valve unit connects the radiator section to the electronics section and connects the storage section to the connecting arrangement (which in turn allows the storage section to be connected to the battery section). This setting may be selected for example in the fourth mode, but also in the first or second mode.

The valve arrangement may advantageously have a third valve unit which is configured to, depending on its setting, either connect the battery section via the connecting arrangement to the first valve unit and to the second valve unit, or separate the battery section from the first valve unit and from the second valve unit. In one state, the third valve unit connects the battery section via the connecting arrangement to the first and to the second valve unit, and in another state, said third valve unit separates the battery section from said valve units. Here, the third valve unit may in particular be arranged between the battery section and the connecting arrangement. It would however also be conceivable for said third valve unit to be arranged within the connecting arrangement or between the connecting arrangement and the first and/or second valve unit.

The valve arrangement preferably has the first, second and third valve units. In principle, embodiments are conceivable which have only one or two of the described valve units, without the numbering indicating a particular preferred selection.

FIGS. 1-5 show example configurations with relative positioning of the various components. If shown directly contacting each other, or directly coupled, then such elements may be referred to as directly contacting or directly coupled, respectively, at least in one example. Similarly, elements shown contiguous or adjacent to one another may be contiguous or adjacent to each other, respectively, at least in one example. As an example, components laying in face-sharing contact with each other may be referred to as in face-sharing contact. As another example, elements positioned apart from each other with only a space there-between and no other components may be referred to as such, in at least one example. As yet another example, elements shown above/below one another, at opposite sides to one another, or to the left/right of one another may be referred to as such, relative to one another. Further, as shown in the figures, a topmost element or point of element may be referred to as a “top” of the component and a bottommost element or point of the element may be referred to as a “bottom” of the component, in at least one example. As used herein, top/bottom, upper/lower, above/below, may be relative to a vertical axis of the figures and used to describe positioning of elements of the figures relative to one another. As such, elements shown above other elements are positioned vertically above the other elements, in one example. As yet another example, shapes of the elements depicted within the figures may be referred to as having those shapes (e.g., such as being circular, straight, planar, curved, rounded, chamfered, angled, or the like). Further, elements shown intersecting one another may be referred to as intersecting elements or intersecting one another, in at least one example. Further still, an element shown within another element or shown outside of another element may be referred as such, in one example. It will be appreciated that one or more components referred to as being “substantially similar and/or identical” differ from one another according to manufacturing tolerances (e.g., within 1-5% deviation).

In the different figures, identical parts are provided with the same reference signs, for which reason these parts are generally also described only once.

FIGS. 1-5 show an embodiment of a cooling system 1 included in a battery-operated electric vehicle (BEV), for example a passenger car or heavy goods vehicle 100. The schematic illustration shows a battery section 2 having a battery 3 that serves as an energy source for various systems of the electric vehicle, in particular also for an electric drive motor 14. The battery section 2 further includes a first pump 5, which serves for conveying a liquid coolant, and a battery heat exchanger 4. Said battery heat exchanger is designed as a liquid/liquid heat exchanger and is incorporated into a refrigerant circuit 40, which may be used inter alia for the air-conditioning of an interior compartment (not illustrated) of the electric vehicle. During operation, the refrigerant circuit 40 conducts a refrigerant which may be compressed via an electric compressor 43 such that the refrigerant is partially liquefied in a condenser 41, releasing heat. The condenser 41 may in turn release heat to the ambient air. In an evaporator 42, the refrigerant may expand, absorbing heat. The refrigerant flow through the evaporator 42 may be shut off via a first shut-off valve 44, and the refrigerant flow through the battery heat exchanger 4 may be interrupted via a second shut-off valve 45.

The drive motor 14 is arranged in an electronics section 10 of the cooling system 1, as are a charger 11, a DC-DC converter 12, and an inverter 13. Further components such as a transmission oil cooler may also be arranged in the electronics section 10. A second pump 15 is arranged in the electronics section 10.

The cooling system 1 may include a radiator section 20 comprising a radiator 21 and may further include a storage section 25 comprising a heat store 26. The radiator 21 is a liquid/air heat exchanger which serves for cooling the cooling liquid and which may be arranged at the front of the vehicle. In this case, the heat store 26 is configured to store heat, that is to say has a high heat capacity. It could alternatively also be configured as a latent heat store or thermochemical heat store.

The electronics branch 10, the radiator branch 20, and the storage branch 25 lead, at one side, into a first directional valve 36 and, at the other side, into a second directional valve 37. Furthermore, a first connecting section 31 leads into the first directional valve 36 and a second connecting section 32 leads into the second directional valve 37. These directional valves 36, 37 are parts of a valve arrangement 35, which also has a third directional valve 38 that connects the two connecting sections 31 and 32 and the battery section 2. The connecting sections 31, 32 together form a connecting arrangement 30.

A control unit 50, which may be implemented in part in software form, is connected via lines (not illustrated) to the valves 36, 37, 38, 44 and 45, to the pumps 5 and 15 and to the compressor 43 and may control these. The lines may be in wired or wireless form. Furthermore, via temperature sensors, the control unit 50 may determine a battery temperature (TB) of the battery 3, an electronics temperature (TE) of the set of power electronics 11-14, a radiator temperature (TR) of the radiator section 20, and a store temperature (TS) of the heat store 26.

FIG. 1 shows a first state of the cooling system 1, in which the first directional valve 36 and the second directional valve 37 connect the electronics section 10 and the radiator section 20 to one another, and a coolant flow is generated via the second pump 15. The storage section 25 is fluidly isolated and is thus bypassed. Here and below, sections without a fluid flow are illustrated in each case by empty (e.g., white filled) arrows, whereas sections with a fluid flow are illustrated by filled (black) arrows. The connecting arrangement 30 is fluidly separated from the battery section 2 via the third directional valve 38. In the battery section, a coolant flow is generated via the first pump 5, with the battery 3 being cooled via the battery heat exchanger 4. The compressor 43 is in operation, such that the refrigerant circuit 40 supplies cooled refrigerant to the battery heat exchanger 4.

FIG. 2 shows a variant of the first state, which differs from the illustration in FIG. 1 by the fact that the first pump 5 and the compressor 43 are inactive. In the alternative first state, cooling of the battery 3 is not executed.

FIG. 3 shows a second state of the cooling system 1, in which the first directional valve 36 and the second directional valve 37 connect the electronics section 10 and the storage section 25 to one another. The second pump 15 is inactive during the second state. Furthermore, said directional valves 36, 37 connect the radiator section 20 to the connecting arrangement 30, which is fluidly connected via the third directional valve 38 to the battery section 2. The first pump 5 generates a coolant flow through the battery section 2, the connecting arrangement 30 and the radiator section 20. The battery 3 is thus cooled via the radiator 21, whilst no cooling of the set of power electronics 11-14 is performed. The compressor 43 is inactive. Additionally or alternatively, the second shut-off valve 45 may be used to stop the fluid flow through the battery heat exchanger 4. In this case, the refrigerant circuit 40 may continue to be used for the air-conditioning of the vehicle interior compartment, if requested.

FIG. 4 shows a third state of the cooling system 1, which differs from the second state by the fact that the second pump 15 is active and thus generates a coolant flow through the electronics section 10 and the storage section 25. Heat is hereby transferred in an effective manner from the set of power electronics 11-14 to the heat store 36.

FIG. 5 shows a fourth state of the cooling system 1, in which the first directional valve 36 and the second directional valve 37 connect the electronics section 10 and the radiator section 20 to one another, and a coolant flow is generated via the second pump 15. Furthermore, the directional valves 36, 37 connect the storage section 25 to the connecting arrangement 30, which is fluidly connected via the third directional valve 38 the battery section 2. The first pump 5 generates a coolant flow through the battery section 2, the connecting arrangement 30 and the storage section 25. The set of power electronics 11-14 is thus cooled via the radiator 21, whilst heat is exchanged between the battery 3 and the heat store 25. In this way, in particular in the event of a cold start, heat may be transferred from the heat store 25 to the battery 3 in order to bring this into an optimum temperature range more quickly. The compressor 43 is inactive.

FIG. 6 shows a flow diagram for a method 600 which illustrates the processes within the cooling system 1, with the processes being controlled in this case by the control unit 50. Instructions for carrying out method 600 may be executed by the control unit based on instructions stored on a memory of the control unit and in conjunction with signals received from sensors of the system, such as the sensors described above with reference to FIGS. 1-5. The control unit may employ actuators of the cooling system 1 to adjust operation, according to the method described below.

The method 600 begins at 602, which includes determining the battery temperature TB, the electronics temperature TE, the radiator temperature TR, and the store temperature TS. The temperatures may be determined via respective temperatures sensors, such as a battery temperature sensor, an electronics temperature sensor, a radiator temperature sensor, and a store temperature sensor. The battery temperature sensor may be coupled to the battery. The electronics temperature sensor may be coupled to an electronic component of the electronics section 10. The radiator temperature sensor may be coupled to the radiator. The store temperature sensor may be coupled to the heat store.

At 604, the method 600 may include determining if the battery temperature TB is less than a lower threshold battery temperature and a store temperature. The lower threshold battery temperature may be based on a non-zero, positive number. The lower threshold battery temperature may correspond to a cold-start temperature of the battery, wherein temperatures lower than the lower threshold battery temperature indicate a cold-start of the battery. If the battery temperature TB is less than the lower threshold battery temperature and the store temperature, then at 606, the method 600 may include entering a fourth mode.

At 608, the method 600 may include cooling the electronics in the electronics section with the radiator and heating the battery with the storage section. Coolant flowing from the radiator to the electronics section may not mix with coolant flowing from the heat store in the storage section to the battery. In one example, each of the first pump and the second pump are active during the fourth mode. The fourth mode may further include where the compressor is inactive. The method 600 may continue to monitor temperatures of the battery system and progress through the method 600 to select different operating modes if a temperature change is determined.

If the battery temperature TB is not less than the lower threshold and the store temperature TS, then at 610, the method 600 may include determining if the electronics temperature TE is less than or equal to an upper threshold electronics temperature. The upper threshold electronics temperature may be based on a non-zero, positive number at which degradation to the electronics may occur. If the electronics temperature TE is greater than the upper threshold electronics temperature, then at 612, the method 600 may include determining if the store temperature TS is less than an upper threshold store temperature TS. The upper threshold store temperature may be based on a non-zero, positive number. The upper threshold store temperature may be based on a temperature of the heat store capable of heating the battery and/or electronic components. In one example, the upper threshold store temperature is a dynamic value based on the electronic temperature. If the store temperature TS is less than the upper threshold store temperature, then the store temperature TS may be increased via coolant cooling the electronics section and at 614, the method 600 may include coupling the storage section to the electronics section. As such, the store temperature TS increases as it cools the electronics section.

If the store temperature is not less than the upper threshold store temperature, then at 618, the method 600 may include coupling the radiator section to the electronics section. As such, the electronics may be cooled by the radiator.

Following yes at 610, yes at 614, and/or no at 612, the method 600 proceeds to 620, which may include determining if the battery temperature TB is less than or equal to an upper threshold battery temperature. The upper threshold battery temperature may be based on a non-zero, positive number above which battery degradation may occur. If the battery temperature is less than the upper threshold battery temperature, then at 622, the method 600 may include deactivating the first pump as activate cooling of the battery is not requested.

If the battery temperature is greater than the upper threshold battery temperature, then at 624, the method 600 may include determining if radiator cooling is provided to the power electronics. Radiator cooling may be provided to the power electronics if the store temperature ST is not less than the upper threshold store temperature, as determined at 612.

If radiator cooling is being provided to the power electronics, then at 626, the method 600 may include entering the first mode.

At 628, the method 600 may include sealing the battery section from the radiator. As such, coolant from the radiator may not flow to the battery.

At 630, the method 600 may include cooling the battery with the battery heat exchanger. The compressor may be activated to provide further cooling if desired.

If radiator cooling is not being provided to the power electronics, then at 632, the method 600 may include determining if a radiator temperature RT is greater than an upper threshold radiator temperature. The upper threshold radiator temperature may be based on a non-zero, positive number, above which cooling may not be provided by the radiator to the entire battery system. If the radiator temperature is not greater than the upper threshold radiator temperature, then the method 600 may proceed to 634, which may include entering the second mode.

At 636, the method 600 may include cooling the battery with the radiator.

At 638, the method 600 may include cooling the electronics with the radiator. As such, thermal demands of the battery and the electronics may be met via cooling provided by the radiator.

If the radiator temperature is greater than the upper threshold radiator temperature, then at 640, the method 600 may include entering the first mode.

At 642, the method 600 may include cooling the battery with the heat exchanger.

Additionally or alternatively, a method may determining the battery temperature TB, the electronics temperature TE, the radiator temperature TR and the store temperature TS. Then, it may be determined whether the battery temperature TB is lower than a minimum temperature, which may occur in the event of a cold start, and whether the store temperature TS is higher than the battery temperature TB. If yes, then the fourth state shown in FIG. 5 is initiated to further the heating of the battery 3. If the battery temperature is not less than the minimum temperature or if the store temperature is not higher than the battery temperature, then a determination is executed as to whether the electronics temperature TE is less than or equal to a first threshold temperature above which the set of power electronics 11-14 may not operate efficiently. If the electronics temperature is above the upper threshold electronics temperature, then the control unit determines if the store temperature TS is less than or equal to an upper threshold store temperature. The upper threshold store temperature is lower than the upper threshold electronics temperature. If store temperature is less than the upper threshold store temperature, then the storage section is connected to the electronics section and the electronics are cooled via the storage section. If the store temperature is not less than the upper threshold store temperature, then the radiator section 20 is connected to the electronics section and cooling is provided by radiator, as shown in the first mode variant illustrated in FIG. 1.

If no demand for cooling the set of power electronics 11-14 is identified or if the electronics are being cooled via the heat store or the radiator, then battery temperature being less than or equal to an upper threshold battery temperature may be determined. If the battery temperature is less than or equal to the upper threshold battery temperature, then there is no demand for cooling the battery 3, and the first pump 5 may be deactivated or kept inactive. The compressor 43 may also be deactivated or remain inactive. In one example, if the electronics are being cooled, then the variant of the first mode shown in FIG. 2 may be executed.

If the battery temperature exceeds the upper threshold battery temperature, then a determination as to whether the electronics are being cooled by the radiator may be executed. If the electronics are being cooled by the radiator, then the battery section 2 is sealed or maintained sealed from the connecting arrangement 30, and cooling of the battery is executed via the battery heat exchanger 4, which corresponds to the first state.

If the set of power electronics 11-14 is not being cooled via the radiator 21, then a determination as to whether the radiator temperature TR exceeds a threshold radiator temperature is executed. The threshold radiator temperature may be lower than the upper threshold battery temperature. If the radiator temperature is higher than the threshold radiator temperature, then effective cooling is not possible via the radiator 21, and the first mode is initiated. If the radiator temperature is less than the threshold radiator temperature, then the battery section 2 is connected via the connecting arrangement 30 to the radiator section 20, which corresponds to the third mode.

The disclosure provides support for a cooling system of an electric vehicle, the cooling system including a battery section comprising a battery, an electronics section comprising a set of power electronics, a radiator section comprising a radiator, a storage section comprising a heat store, and a plurality of valves configured to control a fluid connection between each of the battery section, the electronics section, the radiator section, and the storage section. A first example of the cooling system further includes where the battery section comprises a battery heat exchanger in thermal contact with a refrigerant circuit comprising a compressor. A second example of the cooling system, optionally including the first example, further includes where a controller with computer-readable instructions stored on non-transitory memory thereof that when executed cause the controller to select a first mode in response to an electronics temperature being greater than an upper threshold electronics temperature, the first mode comprising the battery section sealed from the radiator section and from the storage section, wherein the electronics section is fluidly coupled to the radiator section and fluid flowing from the radiator section to the electronics section bypasses the storage section. A third example of the cooling system, optionally including one or more of the previous examples, further includes where the first mode further includes where the battery is fluidly coupled to a battery heat exchanger in response to a battery temperature being greater than an upper threshold battery temperature. A fourth example of the cooling system, optionally including one or more of the previous examples, further includes where the instructions further cause the controller to select a second mode in response to the electronics temperature being less than or equal to the upper threshold electronics temperature and a battery temperature being greater than an upper threshold electronics temperature, the second mode comprising fluidly coupling the battery section to the radiator section and blocking coolant flow to the electronics section and the storage section. A fifth example of the cooling system, optionally including one or more of the previous examples, further includes where the instructions further cause the controller to select a third mode in response to the electronics temperature being greater than the upper threshold electronics temperature, a battery temperature being greater than an upper threshold battery temperature, and a radiator temperature being less than a threshold radiator temperature, wherein the third mode comprises flowing coolant from the radiator section to each of the electronics section, the battery section, and the storage section. A sixth example of the cooling system, optionally including one or more of the previous examples, further includes where the instructions further cause the controller to select a fourth mode in response to a battery temperature being less than a lower threshold battery temperature and the electronics temperature being greater than the upper threshold electronics temperature, wherein the fourth mode comprises fluidly coupling the radiator section to the electronics section and fluidly coupling the storage section to the battery section. A seventh example of the cooling system, optionally including one or more of the previous examples, further includes where the plurality of valves comprises a first valve, a second valve, and a third valve, wherein the first valve is configured to control fluid flow into the electronics section and out of the storage section, the second valve is configured to control fluid flow into the storage section and out of the electronics section, and the third valve is configured to control fluid flow in to the battery section. An eighth example of the cooling system, optionally including one or more of the previous examples, further includes where the battery section comprises a first pump and the electronics section comprises a second pump.

The disclosure provides additional support for a system including a heat exchanger configured to cool a battery arranged in a battery section, a radiator section comprising a radiator configured to cool one or more of the battery and an electronics section comprising a plurality of electronics, a storage section comprising a heat store configured to heat the battery during a cold-start, a first valve configured to control fluid flow out of the storage section and into the electronics section, a second valve configured to control fluid flow out of the electronics section and into the storage section, a third valve configured to control fluid flow into the battery section, and a controller comprising instructions stored in memory that when executed cause the controller to select a first mode, a second mode, a third mode, or a fourth mode in response to one or more of a battery temperature, a radiator temperature, and an electronics temperature. A first example of the system may further include the first mode is selected in response to the electronics temperature being greater than an upper threshold electronics temperature, the first mode comprises where the battery section is sealed from the radiator section and from the storage section, wherein the electronics section is fluidly coupled to the radiator section and fluid flowing from the radiator section to the electronics section bypasses the storage section. A second example of the system, optionally including the first example, further includes where the first mode further includes where the battery is fluidly coupled to the heat exchanger in response to the battery temperature being greater than an upper threshold battery temperature. A third example of the system, optionally including one or more of the previous examples, further includes where the second mode is selected in response to the electronics temperature being less than or equal to an upper threshold electronics temperature and the battery temperature being greater than an upper threshold electronics temperature, the second mode comprising fluidly coupling the battery section to the radiator section and blocking coolant flow to the electronics section and the storage section. A fourth example of the system, optionally including one or more of the previous examples, further includes where the third mode is selected in response to the electronics temperature being greater than an upper threshold electronics temperature, the battery temperature being greater than an upper threshold battery temperature, and the radiator temperature being less than a threshold radiator temperature, wherein the third mode comprises flowing coolant from the radiator section to each of the electronics section, the battery section, and the storage section. A fifth example of the system, optionally including one or more of the previous examples, further includes where the fourth mode is selected in response to the battery temperature being less than a lower threshold battery temperature and the electronics temperature being greater than an upper threshold electronics temperature, wherein the fourth mode comprises fluidly coupling the radiator section to the electronics section and fluidly coupling the storage section to the battery section.

The disclosure provides further support for a method for a cooling system of a vehicle, the cooling system comprising a battery section comprising a battery, an electronics section comprising a set of power electronics, a radiator section comprising a radiator, a storage section comprising a heat store, the method including selecting a first mode in response to an electronics temperature being greater than an upper threshold electronics temperature, the first mode comprising where the battery section is sealed from the radiator section and from the storage section, wherein the electronics section is fluidly coupled to the radiator section and fluid flowing from the radiator section to the electronics section bypasses the storage section, selecting a second mode in response to an electronics temperature being less than or equal to an upper threshold electronics temperature and a battery temperature being greater than an upper threshold electronics temperature, the second mode comprising fluidly coupling the battery section to the radiator section and blocking coolant flow to the electronics section and the storage section, selecting a third mode in response to an electronics temperature being greater than an upper threshold electronics temperature, a battery temperature being greater than an upper threshold battery temperature, and a radiator temperature being less than a threshold radiator temperature, wherein the third mode comprises flowing coolant from the radiator section to each of the electronics section, the battery section, and the storage section, and selecting a fourth mode in response to a battery temperature being less than a lower threshold battery temperature and an electronics temperature being greater than an upper threshold electronics temperature, wherein the fourth mode comprises fluidly coupling the radiator section to the electronics section and fluidly coupling the storage section to the battery section. A first example of the method further includes cooling the battery via the heat exchanger in response to the battery temperature being greater than the upper threshold battery temperature. A second example of the method, optionally including the first example, further includes where the fourth mode is further selected in response to a cold-start. A third example of the method, optionally including one or more of the previous examples, further includes where activating a first pump during the second mode, the third mode, and the fourth mode. A fourth example of the method, optionally including one or more of the previous examples, further includes activating a second pump during the first mode, the third mode, and the fourth mode.

Note that the example control and estimation routines included herein may be used with various powertrain and/or vehicle system configurations. The control methods and routines disclosed herein may be stored as executable instructions in non-transitory memory and may be carried out by the control system including the controller in combination with the various sensors, actuators, and other hardware. The specific routines described herein may represent one or more of any number of processing strategies such as event-driven, interrupt-driven, multi-tasking, multi-threading, and the like. As such, various actions, operations, and/or functions illustrated may be performed in the sequence illustrated, in parallel, or in some cases omitted. Likewise, the order of processing is not necessarily required to achieve the features and advantages of the example embodiments described herein, but is provided for ease of illustration and description. One or more of the illustrated actions, operations and/or functions may be repeatedly performed depending on the particular strategy being used. Further, the described actions, operations and/or functions may graphically represent code to be programmed into non-transitory memory of the computer readable storage medium in the control system, where the described actions are carried out by executing the instructions in a system including the various hardware components in combination with the electronic control unit.

It will be appreciated that the configurations and routines disclosed herein are exemplary in nature, and that these specific embodiments are not to be considered in a limiting sense, because numerous variations are possible. The subject matter of the present disclosure includes all novel and non-obvious combinations and sub-combinations of the various systems and configurations, and other features, functions, and/or properties disclosed herein.

As used herein, the term “approximately” is construed to mean plus or minus five percent of the range unless otherwise specified.

The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

1. A cooling system of an electric vehicle, the cooling system comprising:
a battery section comprising a battery;
an electronics section comprising a set of power electronics;
a radiator section comprising a radiator;
a storage section comprising a heat store; and
a plurality of valves configured to control a fluid connection between each of the battery section, the electronics section, the radiator section, and the storage section.

2. The cooling system of claim 1, wherein the battery section comprises a battery heat exchanger in thermal contact with a refrigerant circuit comprising a compressor.

3. The cooling system of claim 1, further comprising a controller with computer-readable instructions stored on non-transitory memory thereof that when executed cause the controller to select a first mode in response to an electronics temperature being greater than an upper threshold electronics temperature, the first mode comprising the battery section sealed from the radiator section and from the storage section, wherein the electronics section is fluidly coupled to the radiator section and fluid flowing from the radiator section to the electronics section bypasses the storage section.

4. The cooling system of claim 3, wherein the first mode further includes where the battery is fluidly coupled to a battery heat exchanger in response to a battery temperature being greater than an upper threshold battery temperature.

5. The cooling system of claim 3, wherein the instructions further cause the controller to select a second mode in response to the electronics temperature being less than or equal to the upper threshold electronics temperature and a battery temperature being greater than an upper threshold electronics temperature, the second mode comprising fluidly coupling the battery section to the radiator section and blocking coolant flow to the electronics section and the storage section.

6. The cooling system of claim 3, wherein the instructions further cause the controller to select a third mode in response to the electronics temperature being greater than the upper threshold electronics temperature, a battery temperature being greater than an upper threshold battery temperature, and a radiator temperature being less than a threshold radiator temperature, wherein the third mode comprises flowing coolant from the radiator section to each of the electronics section, the battery section, and the storage section.

7. The cooling system of claim 3, wherein the instructions further cause the controller to select a fourth mode in response to a battery temperature being less than a lower threshold battery temperature and the electronics temperature being greater than the upper threshold electronics temperature, wherein the fourth mode comprises fluidly coupling the radiator section to the electronics section and fluidly coupling the storage section to the battery section.

8. The cooling system of claim 1, wherein the plurality of valves comprises a first valve, a second valve, and a third valve, wherein the first valve is configured to control fluid flow into the electronics section and out of the storage section, the second valve is configured to control fluid flow into the storage section and out of the electronics section, and the third valve is configured to control fluid flow in to the battery section.

9. The cooling system of claim 1, wherein the battery section comprises a first pump and the electronics section comprises a second pump.

10. A system, comprising:
a heat exchanger configured to cool a battery arranged in a battery section;
a radiator section comprising a radiator configured to cool one or more of the battery and an electronics section comprising a plurality of electronics;
a storage section comprising a heat store configured to heat the battery during a cold-start;
a first valve configured to control fluid flow out of the storage section and into the electronics section;
a second valve configured to control fluid flow out of the electronics section and into the storage section;
a third valve configured to control fluid flow into the battery section; and
a controller comprising instructions stored in memory that when executed cause the controller to select a first mode, a second mode, a third mode, or a fourth mode in response to one or more of a battery temperature, a radiator temperature, and an electronics temperature.

11. The system of claim 10, wherein the first mode is selected in response to the electronics temperature being greater than an upper threshold electronics temperature, the first mode comprises where the battery section is sealed from the radiator section and from the storage section, wherein the electronics section is fluidly coupled to the radiator section and fluid flowing from the radiator section to the electronics section bypasses the storage section.

12. The system of claim 11, wherein the first mode further includes where the battery is fluidly coupled to the heat exchanger in response to the battery temperature being greater than an upper threshold battery temperature.

13. The system of claim 10, wherein the second mode is selected in response to the electronics temperature being less than or equal to an upper threshold electronics temperature and the battery temperature being greater than an upper threshold electronics temperature, the second mode comprising fluidly coupling the battery section to the radiator section and blocking coolant flow to the electronics section and the storage section.

14. The system of claim 10, wherein the third mode is selected in response to the electronics temperature being greater than an upper threshold electronics temperature, the battery temperature being greater than an upper threshold battery temperature, and the radiator temperature being less than a threshold radiator temperature, wherein the third mode comprises flowing coolant from the radiator section to each of the electronics section, the battery section, and the storage section.

15. The system of claim 10, wherein the fourth mode is selected in response to the battery temperature being less than a lower threshold battery temperature and the electronics temperature being greater than an upper threshold electronics temperature, wherein the fourth mode comprises fluidly coupling the radiator section to the electronics section and fluidly coupling the storage section to the battery section.

16. A method for a cooling system of a vehicle, the cooling system comprising a battery section comprising a battery, an electronics section comprising a set of power electronics, a radiator section comprising a radiator, a storage section comprising a heat store, the method comprising:
selecting a first mode in response to an electronics temperature being greater than an upper threshold electronics temperature, the first mode comprising where the battery section is sealed from the radiator section and from the storage section, wherein the electronics section is fluidly coupled to the radiator section and fluid flowing from the radiator section to the electronics section bypasses the storage section;
selecting a second mode in response to an electronics temperature being less than or equal to an upper threshold electronics temperature and a battery temperature being greater than an upper threshold electronics temperature, the second mode comprising fluidly coupling the battery section to the radiator section and blocking coolant flow to the electronics section and the storage section;
selecting a third mode in response to an electronics temperature being greater than an upper threshold electronics temperature, a battery temperature being greater than an upper threshold battery temperature, and a radiator temperature being less than a threshold radiator temperature, wherein the third mode comprises flowing coolant from the radiator section to each of the electronics section, the battery section, and the storage section; and
selecting a fourth mode in response to a battery temperature being less than a lower threshold battery temperature and an electronics temperature being greater than an upper threshold electronics temperature, wherein the fourth mode comprises fluidly coupling the radiator section to the electronics section and fluidly coupling the storage section to the battery section.

17. The method of claim 16, further comprising cooling the battery via the heat exchanger in response to the battery temperature being greater than the upper threshold battery temperature.

18. The method of claim 16, wherein the fourth mode is further selected in response to a cold-start.

19. The method of claim 16, further comprising activating a first pump during the second mode, the third mode, and the fourth mode.

20. The method of claim 19, further comprising activating a second pump during the first mode, the third mode, and the fourth mode.
